(19) United States
(12) Patent Application Publication
(10) Pub. No.: US 2016/0172295 A1
(43) Pub. Date: Jun. 16, 2016

(54) Power FET Having Reduced Gate Resistance

(71) Applicant: Infineon Technologies Americas Corp., El Segundo, CA (US)

(72) Inventors: Alex Lollio, Pavia (IT); Timothy D. Henson, Mount Shasta, CA (US); Ling Ma, Redondo Beach, CA (US); Harsh Naik, El Segundo, CA (US); Niraj Ranjan, El Segundo, CA (US)

(73) Assignee: INFINEON TECHNOLOGIES AMERICAS CORP.

(21) Appl. No.: 14/956,186

(22) Filed: Dec. 1, 2015

Related U.S. Application Data
(60) Provisional application No. 62/092,423, filed on Dec. 16, 2014.

(51) Int. Cl. H01L 23/528; H01L 27/06; H01L 29/16; H01L 29/423; H01L 29/78; H01L 23/532

(52) U.S. Cl. CPC H01L 23/528; H01L 29/7813; H01L 23/53219; H01L 23/53228; H01L 23/53214; H01L 29/16; H01L 29/4236; H01L 29/7803; H01L 27/0617

(57) ABSTRACT

In one implementation, a power field-effect transistor (FET) having a reduced gate resistance includes a drain, a source, a gate, and a gate contact including a gate pad, a gate highway, and multiple gate buses. The gate buses are formed from a first metal layer having a first thickness, while the gate pad and the gate highway each include a metal stack including the first metal layer and a second metal layer. The second metal layer has a second thickness substantially greater than the first thickness, thereby reducing the gate resistance of the power FET.

The present application claims the benefit of and priority to a provisional application entitled “Multiple Metal Layers to Improve Gate Delay in Power Transistors,” Ser. No. 62/092,423 filed on Dec. 16, 2014. The disclosure in this provisional application is hereby incorporated fully by reference into the present application.

### BACKGROUND

### Background Art

Power converters, such as voltage regulators, are used in a variety of electronic circuits and systems. Many integrated circuit (IC) applications, for instance, require conversion of a direct current (DC) input voltage to a lower, or higher, DC output voltage. For example, a buck converter may be implemented to convert a higher voltage DC input to a lower voltage DC output for use in low voltage applications in which relatively large output currents are required.

The output stage of a power converter typically includes a high side control transistor and a low side synchronous (sync) transistor in the form of power field-effect transistors (FETs). The switching speed and dead time requirements for a power converter including such power FETs are determined, at least in part, by the gate resistance of those FETs. As a result, the implementation of power FETs having reduced gate resistance would be advantageous.

### SUMMARY

The present disclosure is directed to a power field-effect transistor (FET) having reduced gate resistance, substantially as shown in and/or described in connection with at least one of the figures, and as set forth in the claims.

### BRIEF DESCRIPTION OF THE DRAWINGS

FIG. 1 shows a diagram of an exemplary power converter.

FIG. 2 shows a top view of a power field-effect transistor (FET) suitable for use in the power converter of FIG. 1, according to one exemplary implementation.

FIG. 3A shows a cross-sectional view of the exemplary power FET of FIG. 2 along perspective lines 3A-3A in that figure.

FIG. 3B shows a cross-sectional view of the exemplary power FET of FIG. 2 along perspective lines 3B-3B in that figure.

FIG. 3C shows a cross-sectional view of the exemplary power FET of FIG. 2 along perspective lines 3C-3C in that figure.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

As stated above, power converters, such as voltage regulators, are used in a variety of electronic circuits and systems. For instance, integrated circuit (IC) applications may require conversion of a direct current (DC) input voltage to a lower, or higher, DC output voltage. As a specific example, a buck converter may be implemented as a voltage regulator to convert a higher voltage DC input to a lower voltage DC output for use in low voltage applications in which relatively large output currents are required.

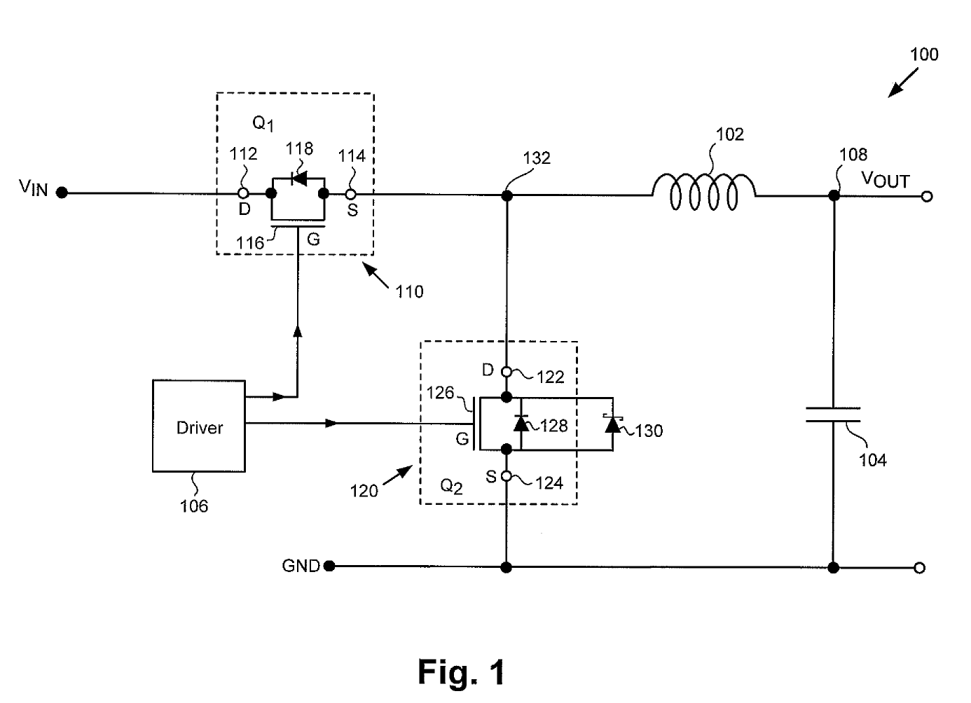

FIG. 1 shows a diagram of an exemplary power converter. As shown in FIG. 1, power converter 100 may be implemented using two power switches in the form of metal-oxide-semiconductor field-effect transistors (MOSFETs) configured as a half bridge, for example. That is to say, power converter 100 may include high side or control FET 110 (Q₁) having drain 112, source 114, gate 116, and body diode 118, as well as low side or synchronous (sync) FET 120 (Q₂) having drain 122, source 124, gate 126, and body diode 128.

In addition, power converter 100 includes output inductor 102, output capacitor 104 and driver 106 for driving respective control and sync FETs 110 and 120. As further shown in FIG. 1, source 114 of control FET 110 is coupled to drain 122 of sync FET 120 at switch node 132, which, in turn, is coupled to output 108 of power converter 100 through output inductor 102. Also shown in FIG. 1, is Schottky diode 130, which is depicted as being coupled in parallel with body diode 128 of sync FET 120.

According to the exemplary implementation shown in FIG. 1, power converter 100 is configured to receive an input voltage V_{IN}, and to provide a converted voltage, e.g., a rectified and/or stepped down voltage, V_{OUT} at output 108. Power converter 100 may be advantageously utilized, for example as a buck converter, in a variety of automotive, industrial, appliance, and lighting applications.

It is noted that in the interests of ease and conciseness of description, the present inventive principles will in some instances be described by reference to specific implementations of a buck converter including one or more silicon based vertical power FETs. However, it is emphasized that such implementations are merely exemplary, and the inventive principles disclosed herein are broadly applicable to a wide range of applications, including buck and boost converters, implemented using other group IV material based, or group III-V semiconductor based, power transistors configured as vertical or lateral power devices.

It is further noted that as used herein, the phrase “group III-V” refers to a compound semiconductor including at least one group III element and at least one group V element. By way of example, a group III-V semiconductor may take the form of a III-Nitride semiconductor that includes nitrogen and at least one group III element. For instance, a III-Nitride power FET may be fabricated using gallium nitride (GaN), in which the group III element or elements include some or a substantial amount of gallium, but may also include other group III elements in addition to gallium. Thus, in some implementations, one or both of control FET 110 and sync FET 120 may take the form of a III-Nitride power FET, such as a III-Nitride high electron mobility transistor (HEMT).

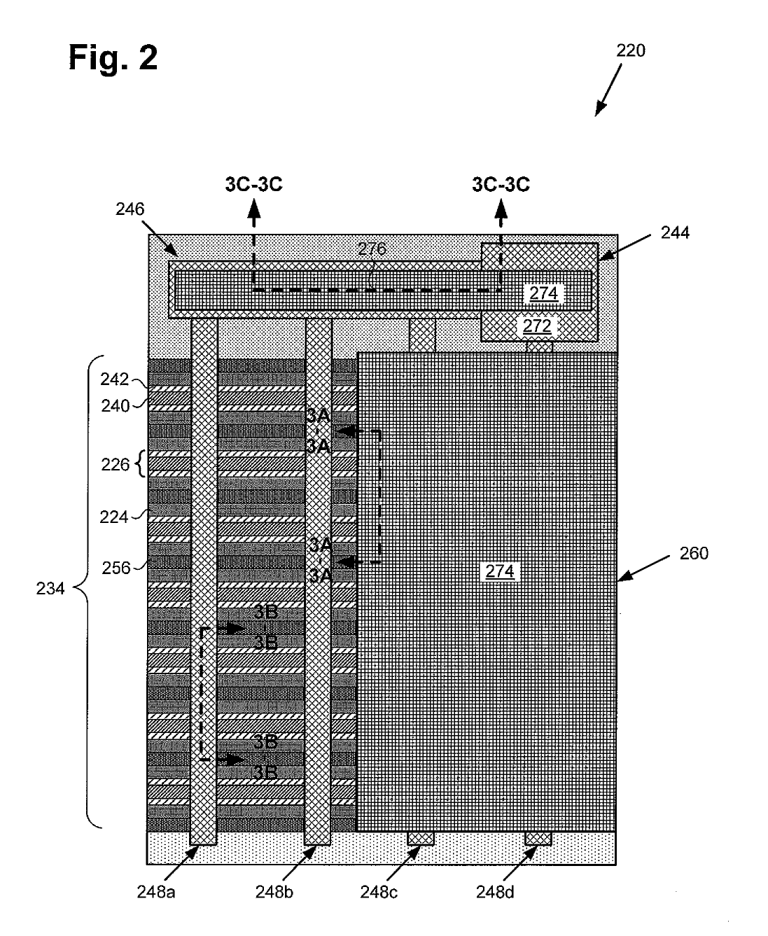

Referring to FIG. 2, FIG. 2 shows a top view of a power FET suitable for use in power converter 100, in FIG. 1, according to one exemplary implementation. Power FET 220 includes active region 234 having gate trenches 226, highly doped source regions 224 adjacent gate trenches 226, and highly doped body diffusions 256. As shown in FIG. 2, gate trenches 226 include gate electrodes 240, and gate dielectric 242 situated between gate electrodes 240 and highly doped source regions 224. Also shown in FIG. 2 are portions of first metal layer 272 providing gate buses 248a, 248b, 248c, and 248d, and also forming part of a metal stack providing gate pad 244 and gate highway 246, as well as portions of second metal layer 274 providing source contact 260 and also forming part of the metal stack providing gate pad 244 and gate highway 246.

As further shown in FIG. 2, a gate voltage for controlling power FET 220 may be applied to gate electrodes 240 via gate pad 244, gate highway 246, and gate buses 248a, 248b, 248c, and 248d. In other words, gate pad 244, gate highway 246, and gate buses 248a, 248b, 248c, and 248d, together, form a gate contact of power FET 220.

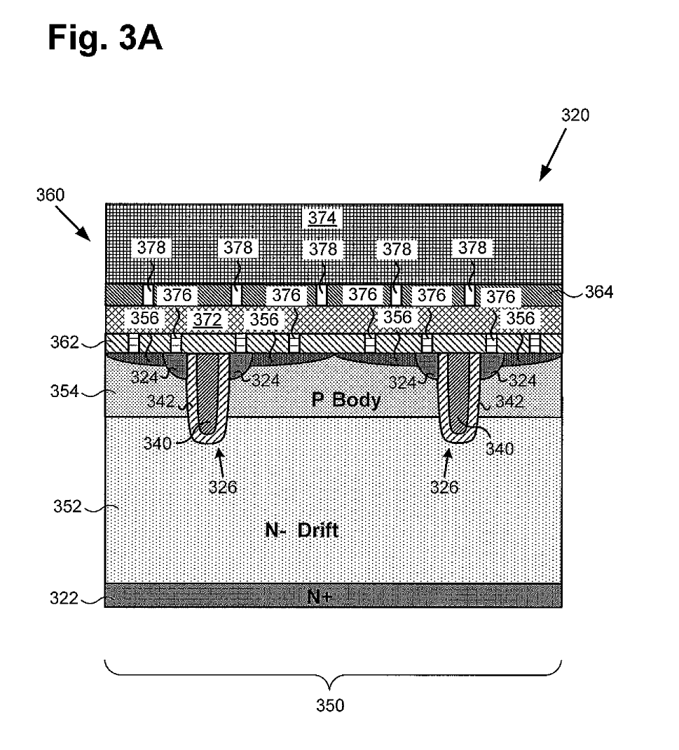

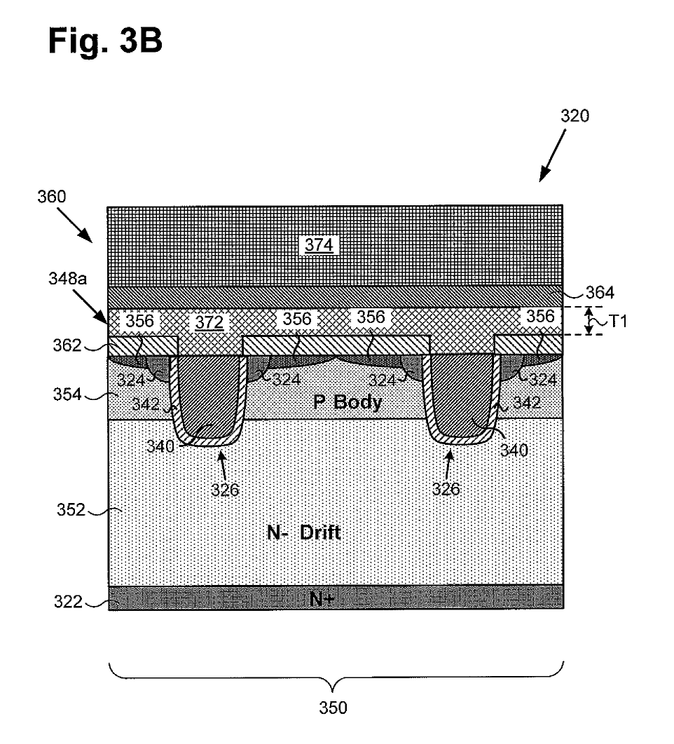

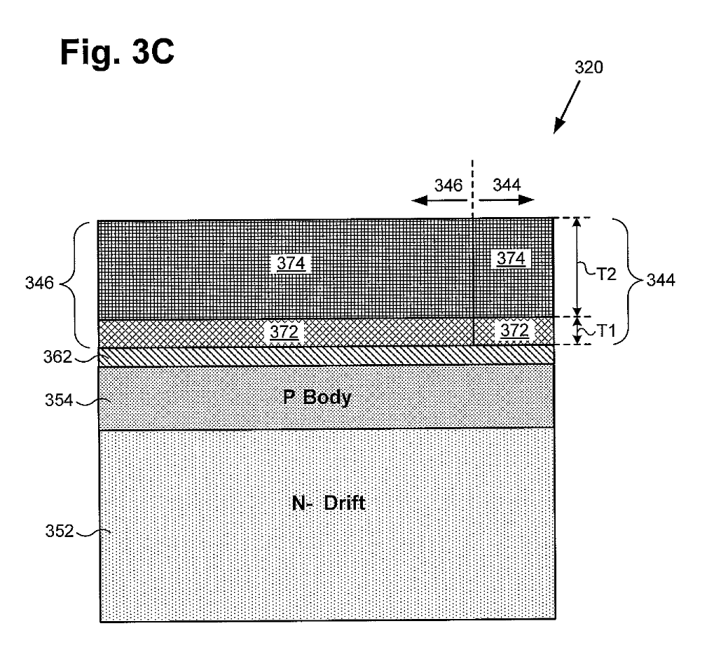

In addition to the features of power FET 220 identified above, FIG. 2 also includes perspective lines 3A-3A, 3B-3B, and 3C-3C corresponding respectively to the cross-sectional views of power FET 220 shown in FIGS. 3A, 3B, and 3C, and described in greater detail below. It is noted that, according to the top view shown in FIG. 2, gate buses 248a, 248b, 248c, and 248d are depicted as though partially seen through second metal layer 274 and a dielectric layer underlying second metal layer 274 (dielectric layer not visible in FIG. 2). Furthermore, gate trenches 226, highly doped source regions 224, and highly doped body diffusions 256 are depicted as though seen through first and second metal layers 272 and 274, as well as one or more dielectric layers (dielectric layer or layers not visible in FIG. 2). Thus, the portions of active region 234 corresponding to perspective lines 3A-3A and 3B-3B are situated under source contact 260.

Power FET 220 corresponds in general to either or both of power FETs 110 and 120, in FIG. 1, and may share any of the characteristics attributed to those corresponding features in the present application. That is to say, power FET 220 may be implemented as one or both of a control FET and a sync FET of a power converter. Furthermore, although power FET 220 is shown as a vertical power device, in FIG. 2, more generally, power FET 220 may take the form of a vertical or lateral power device.

Continuing to FIG. 3A, FIG. 3A shows a cross-sectional view of exemplary vertical power FET 320 along perspective lines 3A-3A in FIG. 2. As shown in FIG. 3A, vertical power FET 320 includes highly doped N type drain 322 at a bottom surface of substrate 350, and N type drift region 352 situated over highly doped N type drain 322. In addition, vertical power FET 320 includes P type body region 354 situated over N type drift region 352, and gate trenches 326 including respective gate electrodes 340 and extending through P type body region 354 into N type drift region 352, as well as highly doped N type source regions 324 adjacent gate trenches 326. FIG. 3A further shows gate dielectric 342 lining gate trenches 326, highly doped P type body diffusions 356, and source contact 360.

Also shown in FIG. 3A are dielectric layer 362 having conductive plugs 376 extending through dielectric layer 362, first metal layer 372, intermetal dielectric 364 having conductive vias 378 extending through intermetal dielectric 364, and second metal layer 374 stacked over first metal layer 372. It is noted that dielectric layer 362 electrically isolates gate electrodes 340 from first and second metal layers 372 and 374.

According to the exemplary implementation shown in FIG. 3A, source contact 360 includes conductive plugs 376, first metal layer 372, conductive vias 378 and second metal layer 374. However, it is further noted that in other implementations, source contact 360 may include fewer features. For example, in one alternative implementation, dielectric layer 362 may be substituted by dielectric caps formed over gate trenches 326, but may otherwise be omitted from the portion of substrate 350 shown in FIG. 3A. In that implementation, conductive plugs 376 may be omitted as well, and first metal layer 372 may make direct electrical contact with highly doped N type source regions 324 and highly doped P type body diffusions 356. In another implementation, dielectric layer 362 as such, conductive plugs 376, intermetal dielectric 364, and conductive vias 378 may be omitted from the portion of substrate 350 shown in FIG. 3A. In that implementation, first metal layer 372 may make direct electrical contact with highly doped N type source regions 324 and highly doped P type body diffusions 356, and second metal layer 374 may be stacked on first metal layer 372.

Vertical power FET 320 corresponds in general to power FET 220, in FIG. 2, and may share any of the characteristics attributed to that corresponding feature in the present application. In other words, highly doped N type source regions 324, and highly doped P type body diffusions 356 correspond in general to respective highly doped source regions 224, and highly doped body diffusions 256, in FIG. 2, and may share any of the characteristics attributed to those corresponding features in the present application. In addition, gate trenches 326 including respective gate electrodes 340 and gate dielectric 342, in FIG. 3A, correspond in general to gate trenches 226 including respective gate electrodes 240 and gate dielectric 242, in FIG. 2, and may share any of the characteristics attributed to those corresponding features in the present application. Moreover, first metal layer 372, second metal layer 374, and source contact 360, in FIG. 3A, correspond in general to first metal layer 272, second metal layer 274, and source contact 260, in FIG. 2, and may share any of the characteristics attributed to those corresponding features in the present application.

It is noted that although the implementation shown in FIG. 3A depicts vertical power FET 320 as an n-channel device having N type drain 322, N type drift region 352, P type body region 354, and N type source regions 324, that representation is merely exemplary. In other implementations, the described polarities can be reversed such that vertical power FET 320 may be a p-channel device having a P type drain, a P type drift region, an N type body region, and P type source regions.

Substrate 350 may be a silicon (Si) substrate or a silicon carbide (SiC) substrate, for example. In some implementations, substrate 350 may include N type drift region 352 and P type body region 354 formed in an epitaxial silicon layer of substrate 350. Formation of such an epitaxial silicon layer may be performed by any suitable method, as known in the art, such as chemical vapor deposition (CVD) or molecular beam epitaxy (MBE), for example. More generally, however, N type drift region 352 and P type body region 354 may be formed in any suitable elemental or compound semiconductor layer included in substrate 350.

Thus, in other implementations, N type drift region 352 and P type body region 354 need not be formed through epitaxial growth, and/or need not be formed of silicon. For example, in one alternative implementation, N type drift region 352 and P type body region 354 can be formed in a float zone silicon layer of substrate 350. In other implementations, N type drift region 352 and P type body region 354 can be formed in either a strained or unstrained germanium layer formed as part of substrate 350.

P type body region 354 and highly doped P type body diffusions 356 may be formed by implantation and thermal diffusion. For example, boron (B) dopants may be implanted into substrate 350 and diffused to form P type body region 354 and highly doped P type body diffusions 356. Highly doped N type source regions 324 may be analogously formed by implantation and thermal diffusion of a suitable N type dopant in substrate 350. Such a suitable N type dopant may include arsenic (As) or phosphorous (P), for example.

Gate electrodes 340 may be formed using any electrically conductive material typically utilized in the art. For example, gate electrodes 340 may be formed of doped polysilicon or metal. Gate dielectric 342 and dielectric layer 362 insulating gate electrodes 340 from source contact 360 may be formed using any material and any technique typically employed in the art. For example, gate dielectric 342 and dielectric layer 362 may be formed of silicon dioxide (SiO₂), and may be deposited or thermally grown to produce respective gate dielectric 342 and dielectric 362. Conductive plugs 376 shown to extend through dielectric layer 362 may be formed as metal plugs, such as tungsten (W) plugs, for example.

First metal layer 372 may be an aluminum (Al) layer, or may be formed of an aluminum alloy, such as aluminum-silicon (Al—Si) or aluminum-silicon-copper (Al—Si—Cu), for example. In some implementations, first metal layer 372 and second metal layer 374 may be formed of the same metal or metal alloy. However, in other implementations, it may be advantageous or desirable to form second metal layer 374 from a different metal or metal alloy than the metal or metal alloy used to form first metal layer 372. Second metal layer 374 may be a copper (Cu) layer, such as a deposited or electroplated Cu layer, for example. However, in other implementations, second metal layer 374 may be formed of Al, or of an aluminum alloy, such as Al—Si or Al—Si—Cu, for example.

According to the exemplary implementation shown in FIG. 3A, intermetal dielectric 364 is formed between first metal layer 372 and second metal layer 374. Intermetal dielectric 364 may be any dielectric material typically utilized as an intermetal dielectric in semiconductor device fabrication. Conductive vias 378 extend through intermetal dielectric 364 to electrically couple second metal layer 374 to first metal layer 372. Conductive vias 378 may be filled with any suitable conductive material, such as Cu or another metal, for example.

Moving to FIG. 3B, FIG. 3B shows a cross-sectional view of exemplary vertical power FET 320 along perspective lines 3B-3B in FIG. 2. It is noted that the features in FIG. 3B identified by reference numbers identical to those appearing in FIG. 3A correspond respectively to those features, as described above, and may share any of the characteristics attributed to those corresponding features in the present application.

In addition to the features described above by reference to FIG. 3A, FIG. 3B further includes gate bus 348a formed from first metal layer 372. Gate bus 348a corresponds in general to gate bus 248a, in FIG. 2, and may share any of the characteristics attributed to that corresponding feature in the present application. Moreover, the characteristics attributed to gate bus 248a/348a are equally applicable as well to gate buses 248b, 248c, and 248d depicted in FIG. 2.

As shown in FIG. 1, source contact 360 is situated over gate bus 348a and is electrically isolated from gate bus 348a by intermetal dielectric 364. As further shown in FIG. 3B, dielectric layer 362 is patterned in the region of vertical power FET 320 shown in FIG. 3B to enable gate bus 348a to make electrical contact with gate electrodes 340, while concurrently insulating highly doped N type source regions 324 and highly doped P type body diffusions 356 from gate bus 348a.

It is noted that in some implementations, as shown in FIG. 3B, gate trenches 326 may have a different dimension or dimensions under gate bus 348a in order to facilitate electrical contact between gate bus 348a and gate electrode 340. For example, and as further shown by comparison of FIGS. 3A and 3B, gate trenches 326 may have a greater width under gate bus 348a than in other regions of active area 234 in which gate trenches 326 are not overlaid by a gate bus corresponding to gate bus 348a.

Gate bus 348a is formed from first metal layer 372, which is shown to have thickness T1. For example, in some implementations, thickness T1 may be in a range from approximately one micrometer to approximately two micrometers (1.0 μm-2.0 μm).

Referring to FIG. 3C, FIG. 3C shows a cross-sectional view of exemplary vertical power FET 320 along perspective lines 3C-3C in FIG. 2. It is noted that the features in FIG. 3C identified by reference numbers identical to those appearing in FIG. 3A or 3B correspond respectively to those features, as described above, and may share any of the characteristics attributed to those corresponding features in the present application.

In addition to the features described above by reference to FIG. 3A and FIG. 3B, FIG. 3C further includes gate pad 344 and gate highway 346. Gate pad 344 and gate highway 346 correspond in general to respective gate pad 244 and gate highway 246, in FIG. 2, and may share any of the characteristics attributed to those corresponding features in the present application.

As shown in FIG. 1, each of gate pad 344 and gate highway 346 includes a metal stack formed from first metal layer 372 and second metal layer 374. For instance, and as further shown in FIG. 3C, second metal layer 374 may be formed directly on first metal layer 372 to provide gate pad 344 and gate highway 346.

Second metal layer 374 has thickness T2 substantially greater than thickness T1 of first metal layer 372. For example, while, as noted above, thickness T1 may be in a range from approximately 1.0 μm to approximately 2.0 μm, for example, thickness T2 may have an exemplary thickness in a range from approximately 5.0 μm to approximately 10.0 μm. Thus, in some implementations, thickness T2 may be three times greater, or more than three times greater, than thickness T1.

It is noted that, although not shown in FIG. 3C, in some implementations, intermetal dielectric 364 may be situated between first metal layer 372 and second metal layer 374 as part of gate pad 344 and gate highway 346. In those implementations, gate pad 344 and gate highway 346 may further include conductive vias 378 extending through intermetal dielectric 364 to electrically couple second metal layer 374 to first metal layer 372.

Thus, referring back to FIG. 2, forming gate pad 244 and gate highway 246 as gate stacks including first metal layer 272 and substantially thicker second metal layer 274 results in a significant increase in the conductive cross-section of gate highway 246 between gate buses 248a, 248b, 248c, and 248d. Consequently, the total gate resistance, and in turn the gate delay, of power FET 220 is substantially reduced. For example, in some implementations, gate resistance and gate delay may be advantageously reduced by approximately fifty percent (50%) when compared to conventional implementions in which gate highway 246 is formed from a relatively thin first metal layer alone. Moreover, when power FET 220 is implemented as a sync FET corresponding to sync FET 120, in FIG. 1, Schottky diode 130 coupled in parallel with body diode 128 of sync FET 120 may be advantageously omitted from power converter 100.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A power field-effect transistor (FET) comprising:
a drain, a source, and a gate;
a gate contact including a gate pad, a gate highway, and a plurality of gate buses;
said plurality of gate buses being formed from a first metal layer having a first thickness;
said gate pad and said gate highway each including a metal stack comprising said first metal layer and a second metal layer;
said second metal layer having a second thickness substantially greater than said first thickness, thereby reducing a gate resistance of said power FET.

2. The power FET of claim 1, wherein said second thickness is at least three times greater than said first thickness.

3. The power FET of claim 1, wherein said first metal layer and said second metal layer comprise a same metal.

4. The power FET of claim 1, wherein at least one of said first metal layer and said second metal layer comprises aluminum.

5. The power FET of claim 1, wherein at least one of said first metal layer and said second metal layer comprises aluminum-silicon.

6. The power FET of claim 1, wherein at least one of said first metal layer and said second metal layer comprises copper.

7. The power FET of claim 1, further comprising a source contact formed from said second metal layer and situated over and electrically isolated from said plurality of gate buses.

8. The power FET of claim 1, wherein said power FET is a vertical group IV FET.

9. The power FET of claim 1, wherein said power FET is a vertical silicon FET.

10. The power FET of claim 1, wherein said power FET is implemented as at least one of a control FET and a sync FET of a power converter.

11. A vertical power field-effect transistor (FET) comprising:
a substrate having a drift region situated over a drain, a body region situated over said drift region, a gate trench having a gate electrode therein and extending into said drift region, and source regions adjacent said gate trench;
a gate contact electrically coupled to said gate electrode, said gate contact including a gate pad, a gate highway, and a plurality of gate buses;
said plurality of gate buses being formed from a first metal layer having a first thickness;
said gate pad and said gate highway each including a metal stack comprising said first metal layer and a second metal layer;
said second metal layer having a second thickness substantially greater than said thickness, thereby reducing a gate resistance of said vertical power FET.

12. The vertical power FET of claim 11, wherein said second thickness is at least three times greater than said first thickness.

13. The vertical power FET of claim 11, wherein said first metal layer and said second metal layer comprise a same metal.

14. The vertical power FET of claim 11, wherein at least one of said first metal layer and said second metal layer comprises aluminum.

15. The vertical power FET of claim 11, wherein at least one of said first metal layer and said second metal layer comprises aluminum-silicon.

16. The vertical power FET of claim 11, wherein at least one of said first metal layer and said second metal layer comprises copper.

17. The vertical power FET of claim 11, further comprising a source contact formed from said second metal layer and situated over and electrically isolated from said plurality of gate buses.

18. The vertical power FET of claim 11, wherein said vertical power FET is a group IV FET.

19. The vertical power FET of claim 11, wherein said vertical power FET is a silicon FET.

20. The vertical power FET of claim 11, wherein said power FET is implemented as at least one of a control FET and a sync FET of a power converter.
